(19) United States
(12) Patent Application Publication
(10) Pub. No.: US 2007/0200063 A1
(43) Pub. Date: Aug. 30, 2007

(54) Wafer-level testing of light-emitting resonant structures

(75) Inventor: Jonathan Gorrell, Gainesville, FL (US)

Correspondence Address: DAVIDSON BERQUIST JACKSON & GOWDEY LLP, 4300 WILSON BLVD., 7TH FLOOR, ARLINGTON, VA, 22203, US

(73) Assignee: Virgin Islands Microsystems, Inc., St. Thomas, VI (US)

(21) Appl. No.: 11/418,124

(22) Filed: May 5, 2006

Related U.S. Application Data
(60) Provisional application No. 60/777,120, filed on Feb. 28, 2006.

(51) Int. Cl. H01J 37/256

(52) U.S. Cl. 250/310; 250/307

(57) ABSTRACT

A device for testing a light-emitting resonant structure on a wafer includes a vacuum chamber for holding the resonant structure; a source of charged particles; a electromagnetic radiation detector; a positioning mechanism constructed and adapted control the position of the wafer within the vacuum chamber; and a controller operatively connected to said source of electrons and to said detector and to said positioning mechanism. A voltage source may be provided.

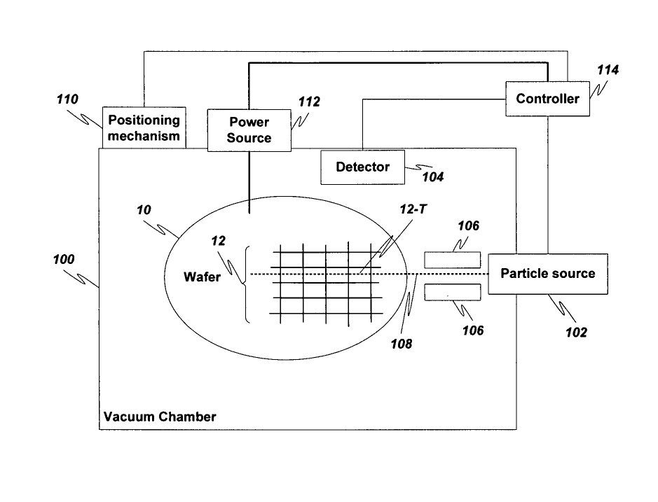

### CROSS-REFERENCE To RELATED APPLICATIONS

Priority Application

This application is related to and claims priority from the following co-pending U.S. patent application, the entire contents of which is incorporated herein by reference: U.S. Provisional Patent Application No. 60/777,120, titled “Systems and Methods of Utilizing Resonant Structures,” filed Feb. 28, 2006.

Related Applications

The present invention is related to the following co-pending U.S. patent applications which are all commonly owned with the present application, the entire contents of each of which are incorporated herein by reference:
1. U.S. application Ser. No. 11/302,471, entitled “Coupled Nano-Resonating Energy Emitting Structures,” filed Dec. 14, 2005,
2. U.S. application Ser. No. 11/349,963, entitled “Method And Structure For Coupling Two Microcircuits,” filed Feb. 9, 2006;
3. U.S. patent application Ser. No. 11/238,991, filed Sep. 30, 2005, entitled “Ultra-Small Resonating Charged Particle Beam Modulator”;
4. U.S. patent application Ser. No. 10/917,511, filed on Aug. 13, 2004, entitled “Patterning Thin Metal Film by Dry Reactive Ion Etching”;
5. U.S. application Ser. No. 11/203,407, filed on Aug. 15, 2005, entitled “Method Of Patterning Ultra-Small Structures”;
6. U.S. application Ser. No. 11/243,476, filed on Oct. 5, 2005, entitled “Structures And Methods For Coupling Energy From An Electromagnetic Wave”;
7. U.S. application Ser. No. 11/243,477, filed on Oct. 5, 2005, entitled “Electron beam induced resonance,”
8. U.S. application Ser. No. 11/325,448, entitled “Selectable Frequency Light Emitter from Single Metal Layer,” filed Jan. 5, 2006;
9. U.S. application Ser. No. 11/325,432, entitled, “Matrix Array Display,” filed Jan. 5, 2006,

10. U.S. patent application Ser. No. 11/400,280, titled “Resonant Detector for Optical Signals,” filed Apr. 10, 2006.

### COPYRIGHT NOTICE

A portion of the disclosure of this patent document contains material which is subject to copyright or mask work protection. The copyright or mask work owner has no objection to the facsimile reproduction by anyone of the patent document or the patent disclosure, as it appears in the Patent and Trademark Office patent file or records, but otherwise reserves all copyright or mask work rights whatsoever.

### FIELD OF THE DISCLOSURE

This relates to ultra-small resonant nanoelectronic devices, and, more particularly, to the wafer-level testing of such devices.

### INTRODUCTION

The related applications describe various ultra-small resonant structures that emit electromagnetic radiation (EMR) when exposed to a beam of charged particles. The ultra-small resonant structure(s) may comprise, for instance, any number of resonant microstructures constructed and adapted to produce EMR, e.g., as described above and/or in U.S. patent applications Ser. Nos. 11/325,448; 11/325,432; 11/243,476; 11/243,477; 11/302,471 (each described in greater detail above). The various ultra-small devices may be made, e.g., using techniques such as described in U.S. patent applications Ser. Nos. 10/917,511; 11/203,407 (described in greater detail above), or in some other manner.

Regardless of the type and number of ultra-small resonant structures on a particular chip, and regardless of the manner of making these structures, it is desirable to test these structures. It is further desirable to test these structures at a wafer level.

### BRIEF DESCRIPTION OF THE DRAWINGS

The following description, given with respect to the attached drawing, may be better understood with reference to the non-limiting examples of the drawing, wherein the drawing shows a testing environment.

### THE PRESENTLY PREFERRED EXEMPLARY EMBODIMENTS

The drawing shows a testing environment for wafer-level testing of ultra-small resonant structures. A wafer 10 includes a number of individual chips generally denoted 12. Each of the so-called chips includes one or more ultra-small resonant structures.

The testing environment includes a vacuum chamber 100, a particle source 102, and a detector 104. The particle source may be any source of charged particles such as an electron source or the like. The detector 104 can detect EMR across an appropriate range of frequencies. In preferred implementations, the detector is constructed and adapted to detect visible light.

Optics 106 are used to position a particle beam 108 emitted by the particle source 102. The environment includes a table or other mechanism that allows individual chips on which a wafer to be accurately positioned with respect to the particle beam 108 and the detector 104. A positioning mechanism 110 controls positioning of the wafer within the vacuum chamber 100. A power source 112 (preferably low voltage) is constructed and adapted to provide power to the various chips on the wafer 10.

The various components (including the particle source, the detector, the power source and the positioning mechanism) are controlled by a controller 114 which may be a general purpose computer constructed and adapted to control the various devices.

In operation, a wafer 10 to be tested is placed on the table within the vacuum chamber 100. A vacuum is created within the chamber and then each chip on the wafer is tested. If a chip contains cathodes, they are preferably tested at low voltage (using the power source 112). The positioning mechanism 110 positions each chip (e.g., chip 12-T) to be tested in an appropriate position with respect to the particle source 102. If needed, the optics 106 control the direction of the particle beam 108 so that it traverses the appropriate portions of the chip under test. The detector checks the output of the chip under test and provides information regarding its detection to the controller which tracks which chips have been tested and which chips have passed (or failed) any tests.

In some embodiments, the particle source 102 may move instead of (or as well as) the wafer in order to position the various chips on the wafer for testing. In such embodiments, the controller 114 controls the position of particle source as needed. In addition, in some embodiments, the detector may also be movable in order to position it for testing various of the chips. Those skilled in the art will thus realize and understand, upon reading this description, that a particular chip (or part of a chip) may be tested by moving one or more of: the wafer itself, the particle source 102 (relative to the wafer) and/or the detector 104.

While certain configurations of structures have been illustrated for the purposes of presenting the basic structures of the present invention, one of ordinary skill in the art will appreciate that other variations are possible which would still fall within the scope of the appended claims. While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

We claim:

1. A device for testing a light-emitting resonant structure on a wafer, the wafer comprising a plurality of chips, at least one of said chips having one or more light emitting structures, the device comprising:
a vacuum chamber for holding the wafer;
a source of charged particles;
a detector; and
a controller operatively connected to each of the source of charged particles and the detector.

2. A device as in claim 1 wherein the source of charged particles comprises a source of electrons.

3. A device as in claim 1 wherein the detector is constructed and adapted to detect electromagnetic radiation.

4. A device as in claim 3 wherein the electromagnetic radiation is visible light.

5. A device as in claim 1 further comprising:
a positioning mechanism constructed and adapted control the position of the wafer within the vacuum chamber, the positioning mechanism being operatively connected to the controller.

6. A device as in claim 1 further comprising:
a mechanism constructed and adapted to control the position of the source of charged particles relative to the wafer, the mechanism being operatively connected to the controller.

7. A device as in claim 1 further comprising:
a mechanism constructed and adapted to vary a position of the detector relative to the wafer, the mechanism being operatively connected to the controller.

8. A device as in claim 5 further comprising:
a mechanism constructed and adapted to control the position of the source of charged particles relative to the wafer, the mechanism being operatively connected to the controller.

9. A device as in claim 1 further comprising:
a power source constructed and adapted to provide power to chips on the wafer, the power source being operatively connected to the controller.

10. A device as in claim 9 wherein the power source is a low-voltage power source.

11. A device for testing a light-emitting resonant structure on a wafer, the wafer comprising a plurality of chips, at least one of said chips having one or more light emitting structures, the device comprising:
a vacuum chamber for holding the resonant structure;
a source of electrons;
a electromagnetic radiation detector;
a positioning mechanism constructed and adapted control the position of the wafer within the vacuum chamber;
a controller operatively connected to said source of electrons and to said detector and to said positioning mechanism.

12. A method of testing an electromagnetic radiation (EMR)-emitting structure on a wafer, said wafer comprising a plurality of chips, at least one of said chips having one or more light emitting structures, the method comprising:
(a) putting the wafer in a chamber and forming a vacuum within the chamber;
(b) positioning the wafer within the chamber so that an EMR-emitting structure on a particular chip of said plurality of chips to be tested is adjacent a path of a beam of charged particles;
(c) providing the beam of charged particles along the path; and
(d) attempting to detect EMR from said EMR-emitting structure.

13. A method as in claim 12 further comprising:
repeating said steps (b) to (d) for at least one other EMR-emitting structure on said particular chip.

14. A method as in claim 12 further comprising:
repeating steps (b) to (d) for at least one other chip on said wafer.

15. A method as in claim 12 further comprising:
providing power to at least one chip on said wafer; and
attempting to detect EMR from at least one EMR-emitting structure on said chip.

16. A method of testing a wafer, said wafer comprising a plurality of chips, at least one of said chips having one or more ultra-small structures constructed and adapted to emit electromagnetic radiation (EMR) in response to a beam of charged particles, the method comprising:
(a) putting the wafer in a chamber and forming a vacuum within the chamber;
(b) for a particular chip of said plurality of chips:
(b1) causing a beam of charged particles to be emitted adjacent at least one ultra-small structure on said particular chip; and
(b2) attempting to detect EMR from said at least one structure.

17. A method as in claim 16, wherein said beam of charged particles emitted in step (b2) is emitted from an off-chip particle source.

18. A method as in claim 17 further comprising:
(c) positioning said particular chip within said chamber so that an EMR-emitting structure on said particular chip is adjacent a path of said beam of charged particles.

19. A method as in claim 16 further comprising:
repeating step (b) for at least one other chip on said wafer.

20. A method as in claim 16 further comprising:
repeating steps (b1) and (b2) for at least one other ultra-small structure on said particular chip.

21. A method as in claim 16, wherein said beam of charged particles emitted in step (b2) is emitted from an on-chip particle source, the method further comprising:
providing power to said particular chip.

22. A method of testing a wafer, said wafer comprising a plurality of chips, at least one of said chips having one or more ultra-small structures constructed and adapted to emit electromagnetic radiation (EMR) in response to a beam of charged particles, the method comprising:
(a) putting the wafer in a chamber and forming a vacuum within the chamber;
(b1) causing a beam of charged particles to be emitted adjacent at least one ultra-small structure on at least one of said chips, said beam of charged particles being emitted by an off-chip particle source;
(b2) responsive to step (b1), attempting to detect EMR from said at least one structure;
(c1) causing another beam of charged particles to be emitted adjacent at least one ultra-small structure on at least one of said chips, said other beam of charged particles being emitted by an on-chip source of charged particles; and
(c2) responsive to step (c1), attempting to detect EMR from said at least one structure.

23. A method as in claim 19 wherein said at least one structure in steps (b1) and (b2) is the same structure as in steps (c1) and (c2).

24. A method of testing an electromagnetic radiation (EMR)-emitting structure on a wafer, said wafer comprising a plurality of chips, at least one of said chips having one or more light emitting structures, the method comprising:
(a) putting the wafer in a chamber and forming a vacuum within the chamber;
(b) causing the wafer to be positioned within the chamber so that an EMR-emitting structure on a particular chip of said plurality of chips to be tested is adjacent a path of a beam of charged particles;
(c) providing the beam of charged particles along the path; and
(d) attempting to detect EMR from said EMR-emitting structure.

25. A method as in claim 24 wherein said step (b) comprises one or more of:
(b1) moving the wafer;
(b2) changing the path of the beam of charged particles.

26. A method as in claim 25 wherein step (b2) comprises:
causing a source of the beam of charged particles to be moved.
